(19) United States
(12) Patent Application Publication
(10) Pub. No.: US 2005/0224951 A1
(43) Pub. Date: Oct. 13, 2005

(54) Jet-dispensed stress relief layer in contact arrays, and processes of making same

(76) Inventors: Daewoong Suh, Phoenix, AZ (US); Christos P. Economopoulos, Phoenix, AZ (US); Saikumar Jayaraman, Chandler, AZ (US); Mohd Erwan P. Basiron, Perai (MY); Sheau Hooi Lim, Penang (MY); Yoong Tatt P. Chin, Bayan Lepas (MY)

Correspondence Address: SCHWEGMAN, LUNDBERG, WOESSNER & KLUTH, P.A., P.O. BOX 2938, MINNEAPOLIS, MN, 55402-0938, US

(21) Appl. No.: 10/815,565

(22) Filed: Mar. 31, 2004

(51) Int. Cl. H01L 23/12; H01L 21/48

(52) U.S. Cl. 257/701; 438/126; 438/615; 257/737; 257/787

(57) ABSTRACT

A stress-relief layer is formed by dispensing a polymer upon a substrate lower surface under conditions to partially embed a solder bump that is disposed upon the lower surface. The stress-relief layer flows against the solder bump. An article that exhibits a stress-relief layer with a structure characteristic of the manner of dispensing is also included. A computing system that includes a stress-relief layer with a structure characteristic of the manner of dispensing is also included.

### TECHNICAL FIELD

Disclosed embodiments relate to a stress-relief layer in a microelectronic device package. The stress-relief layer assists in preventing thermal mismatch and creep failures in microelectronic device packages.

### BACKGROUND INFORMATION

Chip packaging is often intensely involved with heat removal. Thermal expansion-mismatch challenges exist between the die, the underfill material, and the substrate to which the die is mounted and to connecting structures such as the motherboard. The thermal mismatch often is exhibited at the joint of a solder bump and its bond pad.

One method of dealing with solder bump stress on a motherboard is to encapsulate the solder bumps at the corners with an underfill layer. This method only encapsulates solder bumps at the periphery of the package. It does not encapsulate the solder bumps at the center.

Future packaging technology, especially in the chipset application will drive finer pitch as package size shrinks. With miniaturization of pitch, smaller ball size poses an increasing challenge to solder joint performance.

### BRIEF DESCRIPTION OF THE DRAWINGS

In order to understand the manner in which embodiments are obtained, a more particular description of various embodiments briefly described above will be rendered by reference to the appended drawings. These drawings depict embodiments that are not necessarily drawn to scale and are not to be considered to be limiting in scope. Some embodiments will be described and explained with additional specificity and detail through the use of the accompanying drawings in which:

FIG. 1A is a cross-section elevation of a chip package during processing according to an embodiment;

FIG. 1B is a cross-section elevation of the chip package depicted in FIG. 1A during further processing according to an embodiment;

FIG. 1C is a cross-section elevation of the chip package depicted in FIG. 1B during further processing according to an embodiment;

FIG. 1D is a cross-section elevation of the chip package depicted in FIG. 1C during further processing according to an embodiment;

FIG. 2 is a detail section taken from FIG. 1B according to an embodiment;

FIG. 3 is a detail section taken from FIG. 1B according to an embodiment;

FIG. 4 is a detail section taken from FIG. 1B according to an embodiment;

FIG. 5 is a detail section taken from FIG. 1B according to an embodiment;

FIG. 6A is a plan of a chip package during processing according to an embodiment;

FIG. 6B is a plan of the chip package depicted in FIG. 6A during further processing according to an embodiment;

FIG. 7A is a plan of a chip package during processing according to an embodiment;

FIG. 7B is a plan of the chip package depicted in FIG. 7A during further processing according to an embodiment;

FIG. 8 is a plan of a chip package during processing according to an embodiment;

FIG. 9 is a detail of the chip package depicted in FIG. 8;

FIG. 10 is a process flow diagram according to an embodiment; and

FIG. 11 is a depiction of a computing system according to an embodiment.

### DETAILED DESCRIPTION

The following description includes terms, such as upper, lower, first, second, etc. that are used for descriptive purposes only and are not to be construed as limiting. The embodiments of a device or article described herein can be manufactured, used, or shipped in a number of positions and orientations. The terms “die” and “processor” generally refer to the physical object that is the basic workpiece that is transformed by various process operations into the desired integrated circuit device. A board is typically a conductor-overlay structure that is insulated and that acts as a mounting substrate for the die. A board is usually singulated from a board array. A die is usually singulated from a wafer, and wafers may be made of semiconducting, non-semiconducting, or combinations of semiconducting and non-semiconducting materials.

A “solder bump” or “electrical bump” is understood to be a unit of electrically conductive material such as a tin-lead solder, a tin-indium solder, a tin-bismuth solder, a tin-silver solder, or other solders that are used in the microelectronic arts. The terms “solder bump” and “electrical bump” can be used interchangeably. Additionally, other electrical communication structures can be used.

Reference will now be made to the drawings wherein like structures will be provided with like reference designations. In order to show the structure and process embodiments most clearly, the drawings included herein are diagrammatic representations of embodiments. Thus, the actual appearance of the fabricated structures, for example in a photomicrograph, may appear different while still incorporating the essential structures of embodiments. Moreover, the drawings show only the structures necessary to understand the embodiments. The embodiments may be referred to, individually and/or collectively, herein by the term “invention” merely for convenience and without intending to voluntarily limit the scope of this disclosure to any single invention or inventive concept if more than one is in fact disclosed. In some embodiments, additional structures known in the art may not have been included to maintain the clarity of the drawings.

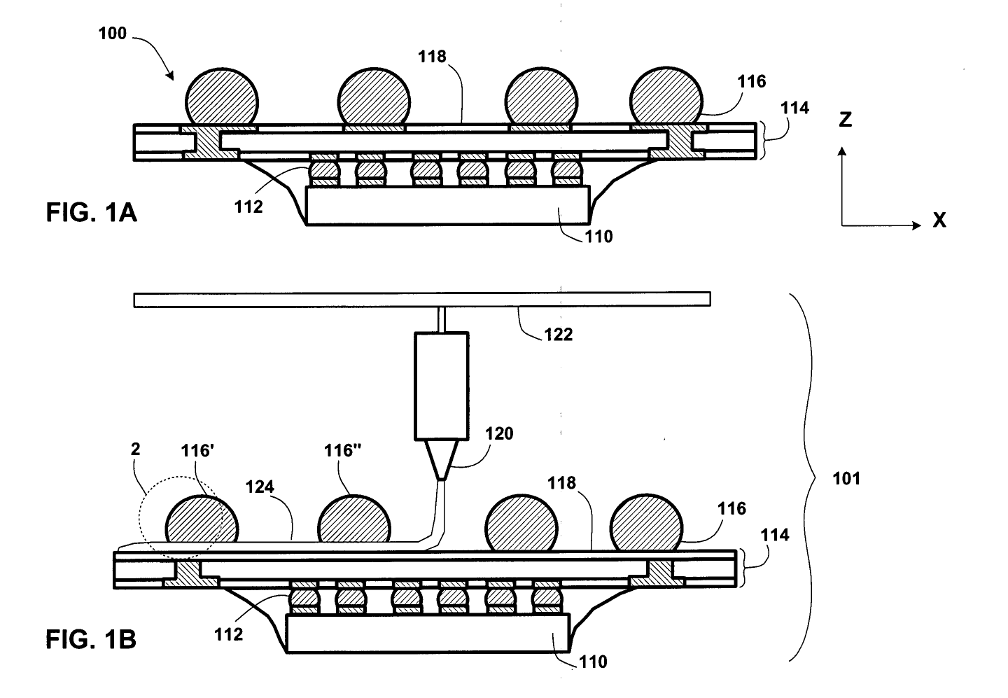

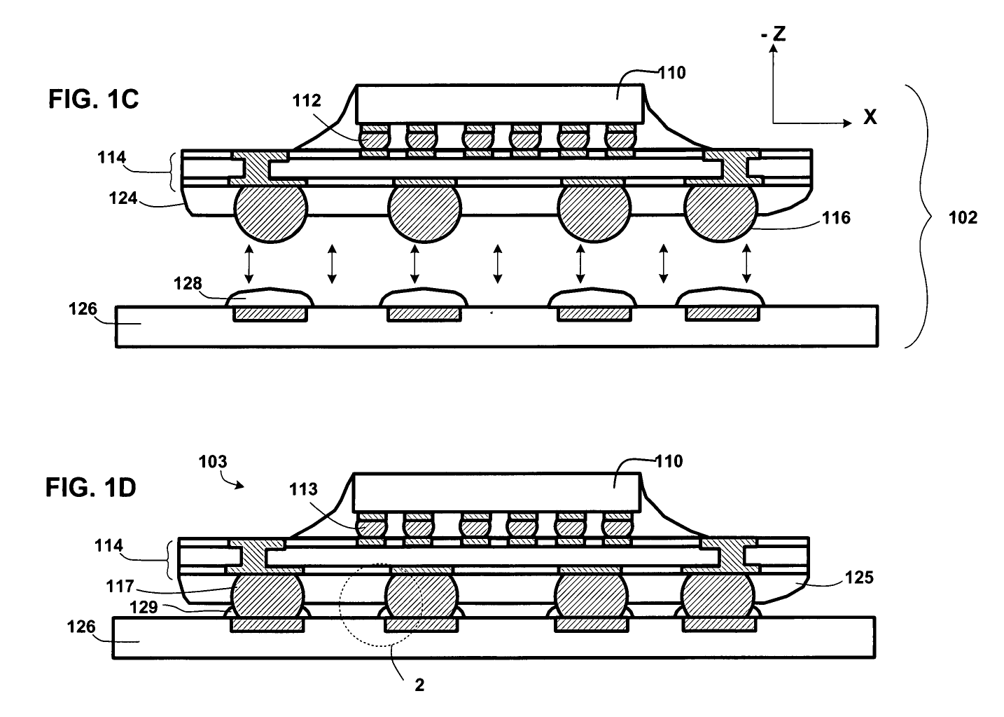

FIG. 1A is a cross-section elevation of a chip package 100 during processing according to an embodiment. The chip package 100 includes a die 110 that is coupled through a plurality of die solder bumps, one of which is designated with the reference numeral 112. In an embodiment, the chip package 100 includes chip-scale packaging dimensions. By “chip-scale packaging dimensions”, it is meant that the footprint of the chip package 100 is in a range from about 120% the largest characteristic dimension of the die 110, to about 200% the largest characteristic dimension of the die 110. Where the die 110 is substantially square, the largest characteristic dimension is an edge of the die 110.

Only six die solder bumps 112 are depicted for clarity of illustration. The die solder bump 112 couples the die 110 to a substrate 114, which is depicted as a laminated structure. The die solder bump 112 is disposed on the die side of the substrate 114.

In an embodiment, the substrate 114 is a second level substrate such as an interposer for a processor. In an embodiment, the substrate 114 is part of a printed wiring board (PWB) such as a main board. In an embodiment, the substrate 114 is part of a mezzanine PWB. In an embodiment, the substrate 114 is part of an expansion card PWB. In an embodiment, the substrate 114 is part of a small PWB such as a board for a handheld device such as a cell phone or a personal digital assistant (PDA). In an embodiment, the substrate 114 is the base board of a device such as a hand-held, and the stress-relief layer technology set forth in this disclosure is applied to the die solder bump 112.

In an embodiment the chip package 100 is also bumped on the land side 118 of the substrate 114 by a plurality of pre-attached solder first bumps, one of which is designated with the reference numeral 116. Although only four solder first bumps 116 are depicted, the number is reduced for clarity of illustration. Where the expression “solder bump” or something enumerating a solder bump in a sequence is set forth, it is understood that it is an electrical coupling as well as a mechanical coupling. Consequently, the term solder bump is synonymous with “electrical bump” where other electrical couplings can be interchanged with a solder coupling.

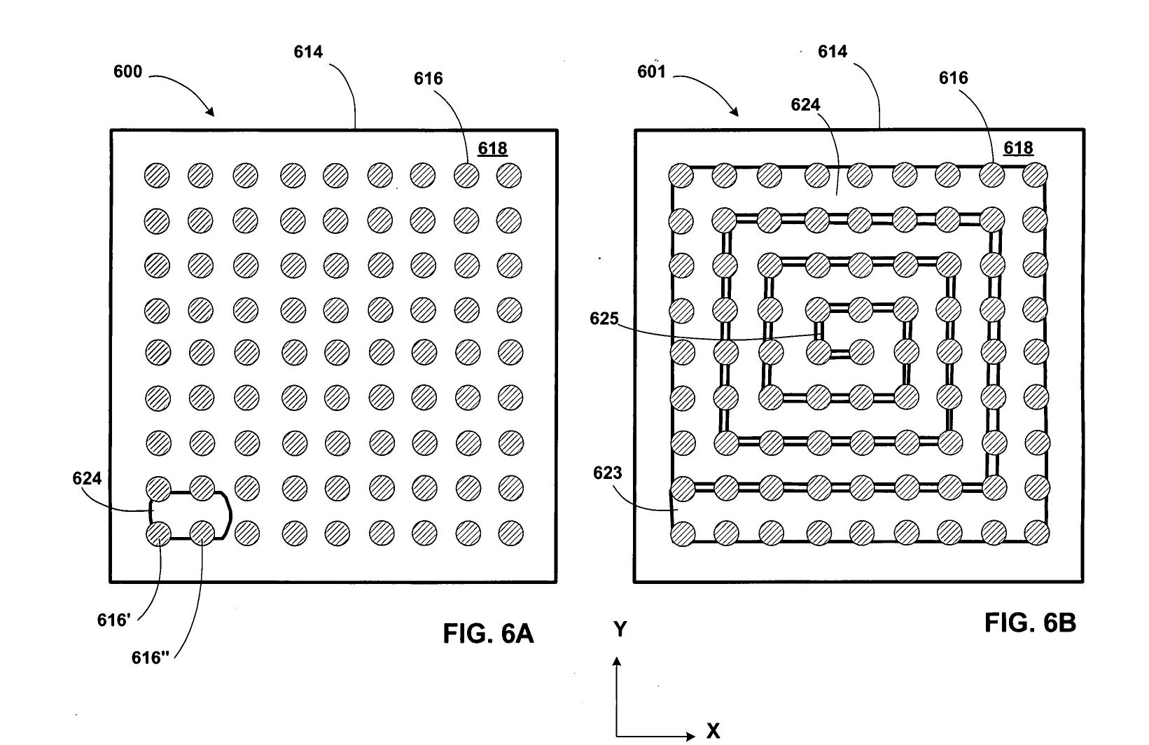

FIG. 1B is a cross-section elevation of the chip package 100 depicted in FIG. 1A during further processing according to an embodiment. The chip package 101 is depicted in connection with a dispenser 120 that is operated with an X-Y gantry 122 according to an embodiment. The dispenser 120 and the X-Y gantry 122 can be obtained from a commercial vendor such as Asymtek of Carlsbad, Calif., which manufactures jet-ejecting equipment. The dispenser 120 is depicted dispensing a substantially continuous stream of a mass such as a polymer underfill material 124 to partially embed the electrical first bump 116. In an embodiment, the dispenser 120 dispenses a substantially discrete series of a quanta of polymer underfill material (see FIGS. 6A, 8, and 9).

Various materials are used as the underfill material 124, including resins according to an embodiment. In an embodiment, an epoxy is used. In an embodiment, a cyanate ester composition or the like is used. In an embodiment, a polyimide composition or the like is used. In an embodiment, a polybenzoxazole composition or the like is used. In an embodiment, a polybenzimidazole composition or the like is used. In an embodiment, a polybenzothiazole composition or the like is used. In an embodiment, a combination of any two of the compositions is used. In an embodiment, a combination of any three of the compositions is used. In an embodiment, a combination of any four of the compositions is used. In an embodiment, a combination of all five of the compositions is used. Other polymer compositions can be used as the underfill material alone, or in combination with the enumerated polymer compositions.

In an embodiment, a polybenzoxazole is used by ejecting it onto the land side 118 in place, and by curing. In an embodiment, curing includes thermal curing the polymer(s). In an embodiment, curing includes cross-link curing the polymer(s). In an embodiment, curing includes cyclization curing the polymer(s). In an embodiment, curing includes at least two of the above curing operations.

In an embodiment, a prepolymer is in non-cyclized form as it is ejected onto the land side 118 before it is further processed, such as by heating to a temperature over its glass transition temperature (T_{G}). Upon heating, the prepolymer begins to cyclize and thereby cure, by reacting with functional groups nearby, and in the process by releasing water molecules. This cyclization changes the prepolymer from its non-cyclized state to its cyclized state, and to different properties that are exhibited between the two states.

In an embodiment, a stress-relief layer is a polybenzoxazole prepolymer that is synthesized by reacting di hydroxylamines with di acids, to form a hydroxy amide. The hydroxy amide is ejected onto the land side 118 of the substrate 114 and is heated by infrared (IR) heating, by microwave heating, or by a combination thereof. Other heating such as conductive and/or convective heating may be carried out. The heating process begins to convert the prepolymer to a closed-ring polybenzoxazole.

In an embodiment, the thermal stability of the stress-relief layer 124 exceeds about 450° C. Generally, the stress-relief layer (SRL) 124 is substantially chemically inert and substantially insoluble after thermal processing. In an embodiment the SRL 124 has a dielectric constant in a range from about 1 to about 3. In an embodiment, the SRL 124 has a dielectric constant of about 2.5.

In an embodiment, a poly (o-hydroxyamide) precursor is dissolved and ejected onto the land side 118 of the substrate 114 as an uncured SRL 124. The uncured SRL 124 is in a non-cyclized state. The T_{G} of the hydroxyamide is also about 75 to 100° C. lower than when the SRL 124 is further cured. The hydroxyamide is next cured to a temperature of about 75 to 100° C. higher than the uncured T_{G}. Curing allows the stress-relief layer 124 to retain permanent features. During thermal processing, conversion of uncured polymer from a poly(hydroxyamide) to a fully cyclized poly benzoxazole stress-relief layer 124 occurs. The T_{G} shifts upwardly to about 75 to 100° C. higher than the uncured SRL 124.

FIG. 1C is a cross-section elevation of the chip package 101 depicted in FIG. 1B during further processing according to an embodiment. The chip package 102 is being mated to a board 126. Processing depicted in FIG. 1C includes the substrate 114 having been inverted and the substrate 114 and the board 126 are being directed toward each other as indicated by the directional arrows.

In an embodiment, the board 126 is prepared with a plurality of pre-applied solder flux spots, one of which is referenced with the reference numeral 128. The pre-applied solder flux spots 128 prevent reflow degradation of the solder first bumps 1 16. Solder flux reacts chemically at increasing temperatures to release acids that reduce metal-oxides that are present between the bond pad and the solder first bump 116.

FIG. 1D is a cross-section elevation of the chip package 102 depicted in FIG. 1C during further processing according to an embodiment. The chip package 103 has been mated by assembling the die 110 and the substrate 114 onto which it is mounted, with the board 126. Assembly has been accomplished by pushing the solder first bumps 116 through the pre-applied solder flux spots 128 (FIG. 1C). Thereafter, the solder flux spots 128 are depicted as a flux residue 129, if they are present at all.

After applying the substrate 114 to the board 126, the SRL 125 (if it has not yet been processed) is cured by any curing process that is appropriate for the specific materials selected for the SRL 125. In an embodiment, prior to, following, or simultaneously with curing the SRL 125, reflowing of the solder first bumps 117 is accomplished. Optionally, the die solder bumps 113 are also reflowed simultaneously therewith.

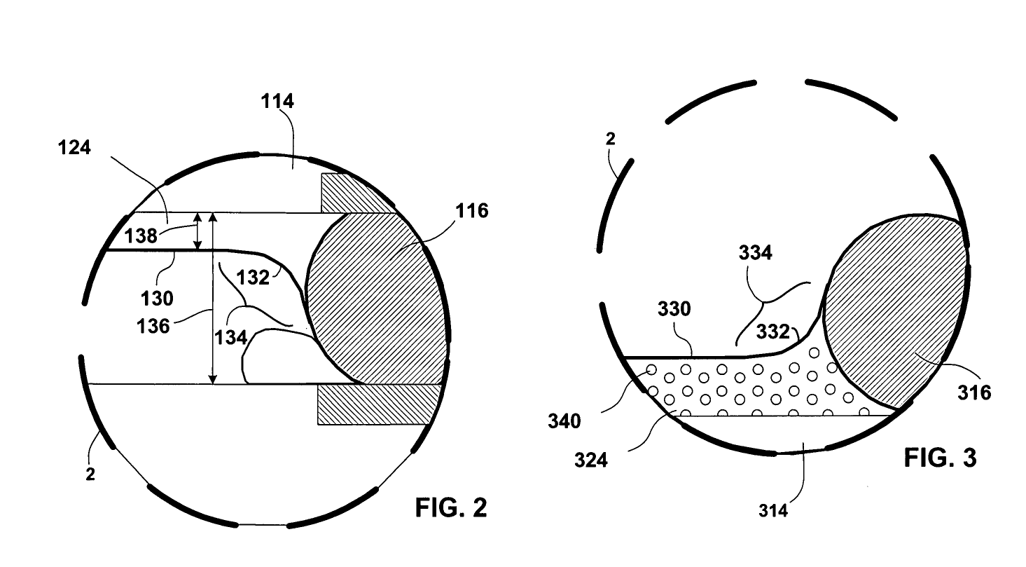

FIG. 2 is a detail section 2 taken from FIG. 1B according to an embodiment. The detail section 2 illustrates the topology of the chip package 101 at an occurrence of a solder first bump 116 and the stress-relief layer 124. Various metrics can be used to quantify the resulting structure that includes the solder first bump 116 in relation to the stress-relief layer 124.

The SRL 124 includes a distal surface 130 and a fillet surface 132. The fillet surface 132 has an arc length 134 that is characteristic of the processing conditions of the SRL 124 according to the various embodiments set forth in this disclosure. The fillet surface 132 is disposed between the distal surface 130 and the solder first bump 116. Together, the distal surface 130 and the fillet surface 132 make up the free surface of the SRL 124. The solder first bump 116 includes a major vertical characteristic dimension 136. The distal surface 130 of the SRL 124 has a height 138 above the substrate 114 that is a fraction of the major vertical characteristic dimension 136 of the solder first bump 116.

In an embodiment, the combination of the distal surface 130 and the fillet surface 132 of the SRL 124 exhibit a surface profile that is characteristic of process conditions including the flow rate of the ejected underfill layer 124 and its wetting characteristics upon the solder first bump 116. In an embodiment, the wetting characteristics are such as are depicted in FIG. 2, wherein the fillet surface 134 ascends along the solder first bump 116 above the distal surface 130. Accordingly, the surface profile exhibits both the distal surface 130 and the fillet surface 132.

In an embodiment, the amount of the solder first bump 116 that is exposed above the distal surface 130 is about seven-eighths or greater, measured by the height 138, divided by the major vertical characteristic dimension 136. In an embodiment, the amount is about one-fourth. In an embodiment, the amount is about 90%. In an embodiment, the amount is about three-fourths. In an embodiment, the amount is about five-eighths. In an embodiment, the amount is about one-half. In an embodiment, the amount is about three-eighths. In an embodiment, the amount is about one-eighth or less. In an embodiment, the amount is about 10%. In an embodiment, the amount is in a range from about 5% to about 95%.

FIG. 3 is a detail section 2 taken from FIG. 1B according to an embodiment. The detail section 2 illustrates the topology of the chip package 101 at an occurrence of a solder first bump 316 and a stress-relief layer (SRL) 324 that abuts a substrate 314 and the solder first bump 316. The chip package includes the solder first bump 316 and the SRL 324. The SRL 324 includes a distal surface 330 and a fillet surface 332. The fillet surface 332 has an arc length 334 that is characteristic the processing conditions of the SRL 324.

Additionally, the SRL 324 is filled with a particulate 340 that assists the stress-relief layer 324 to have a coefficient of thermal expansion (CTE) that facilitates a lower thermal mismatch between neighboring structures. In an embodiment, the particulate 340 is silica or the like. In an embodiment, the particulate 340 is ceria or the like. In an embodiment, the particulate 340 is zirconia or the like. In an embodiment, the particulate 340 is thoria or the like. In an embodiment, the particulate 340 is a combination of two or more particulates. Other dielectric particulates 340 may be used alone, or in combination with enumerated particulates.

In an embodiment, the particulate 340 is present in a range from about 1 percent to about one-half or greater the total weight of the SRL 324 after it has been fully cured for field use. In an embodiment, the particulate 340 is in a range from about 2 percent to about 30 percent. In an embodiment, the particulate 340 is in a range from about 5 percent to about 25 percent. In an embodiment, the particulate 340 is in a range from about 10 percent to about 20 percent.

The coefficient of thermal expansion (CTE) of the SRL 324 is alterable by the presence and weight percent of the particulate 340. In an embodiment, the SRL 324 as filled with the particulate (hereinafer SRL 324) includes a composite CTE in a range from about 9 ppm/° C. to about 40 ppm/° C. In an embodiment, the SRL 324 includes a composite CTE in a range from about 15 ppm/° C. to about 35 ppm/° C. In an embodiment, the SRL 324 includes a composite CTE in a range from about 20 ppm/° C. to about 30 ppm/° C. The specific CTE can be selected within these ranges, or outside these ranges according to an application, and can be selected to balance adhesion of the SRL 324 to the substrate 314 and to provide stress-relieving qualities based upon a known thermal load under operating conditions of the die.

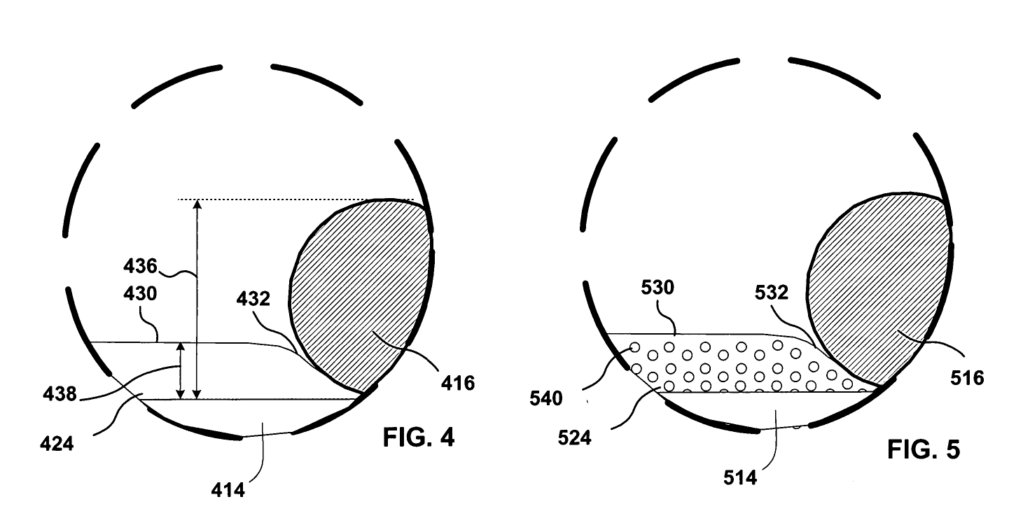

FIG. 4 is a detail section 2 taken from FIG. 1B according to an embodiment. The detail section 2 illustrates the topology of the chip package 101 at an occurrence of a solder first bump 416 and a stress-relief layer (SRL) 424 upon a substrate 414. Various metrics can be used to quantify the resulting structure that includes the solder first bump 416 in relation to the SRL 424.

The SRL 424 includes a distal surface 430 and a non-wetting surface 432. The non-wetting surface 432 is characteristic of low viscosity of the SRL 424 in relation to its wetting ability against the solder first bump 416.

The distal surface 430 of the SRL 424 has a height 438 that is a fraction of the diameter 436 of the solder first bump 416. In an embodiment, the combination of the distal surface 430 and the non-wetting surface 432 of the SRL 424 exhibit a surface profile that is characteristic of process conditions including the flow rate of the ejected underfill layer 424 and its wetting characteristics upon the solder first bump 416. In an embodiment, the wetting characteristics are such as are depicted in FIG. 4, wherein the non-wetting surface 432 exhibits subduction along the solder first bump 416. Accordingly, the surface profile exhibits both the distal surface 430 and the non-wetting surface 432.

In an embodiment, the amount of the solder first bump 416 that is exposed above the distal surface 430 is about seven-eighths or greater, as measured by the height 438 divided by the diameter 436. In an embodiment, the amount is about 90%. In an embodiment, the amount is about three-fourths. In an embodiment, the amount is about five-eighths. In an embodiment, the amount is about one-half In an embodiment, the amount is about three-eighths. In an embodiment, the amount is about one fourth. In an embodiment, the amount is about one-eighth or less. In an embodiment, the amount is about 10%. In an embodiment, the amount is in a range from about 5% to about 95%.

FIG. 5 is a detail section 2 taken from FIG. 1B according to an embodiment. The detail section 2 illustrates the topology of the chip package 101 at an occurrence of a solder first bump 516 and a stress-relief layer (SRL) 524 that abuts a substrate 514 and the solder first bump 516. The chip package includes the solder first bump 516 and the SRL 524. The SRL 524 includes a distal surface 530 and a non-wetting surface 532. The non-wetting surface 532 is characteristic of low viscosity of the SRL 524 in relation to its wetting ability against the solder first bump 516.

Additionally, the SRL 524 is filled with a particulate 540 that assists the stress-relief layer 524 to have a CTE that facilitates a lower thermal mismatch between neighboring structures. In an embodiment, the particulate 540 is silica or the like. In an embodiment, the particulate 540 is ceria or the like. In an embodiment, the particulate 540 is zirconia or the like. In an embodiment, the particulate 540 is thoria or the like. In an embodiment, the particulate 540 is a combination of two or more particulates. Other dielectric particulates 540 may be used alone, or in combination with enumerated particulates.

In an embodiment, the particulate 540 is present in a range from about 1 percent to about one-half or greater the total weight of the SRL 524 after it has been fully cured for field use. In an embodiment, the particulate 540 is in a range from about 2 percent to about 30 percent. In an embodiment, the particulate 540 is in a range from about 5 percent to about 25 percent. In an embodiment, the particulate 540 is in a range from about 10 percent to about 20 percent.

The CTE of the stress-relief layer 524 is alterable by the presence and amount of the particulate 540. In an embodiment, the SRL 524 as filled with the particulate (hereinafer SRL 524) includes a composite CTE in a range from about 9 ppm/° C. to about 40 ppm/° C. In an embodiment, the SRL 524 includes a composite CTE in a range from about 15 ppm/° C. to about 35 ppm/° C. In an embodiment, the SRL 524 includes a composite CTE in a range from about 20 ppm/° C. to about 30 ppm/° C. The specific CTE can be selected within these ranges, or outside these ranges according to an application, and can be selected to balance adhesion to the substrate 514 and to provide stress-relieving qualities based upon a known thermal load under operating conditions of the die.

FIG. 6A is a plan of a chip package 600 during processing according to an embodiment. The chip package 600 includes a die (not pictured) that is coupled through a plurality of die solder bumps on the land side thereof, one of which is designated with the reference numeral 616.

In an embodiment, the substrate 614 is a second level substrate such as an interposer for a processor. In an embodiment, the substrate 614 is part of a printed wiring board (PWB) such as a main board. In an embodiment, the substrate 614 is part of a mezzanine PWB. In an embodiment, the substrate 614 is part of an expansion card PWB. In an embodiment, the substrate 614 is part of a small PWB such as a board for a handheld device such as a cell phone or a personal digital assistant (PDA). In an embodiment, the die is represented as the substrate 614 and the land side 618 is represented as the active surface of the die 614 after appropriate metallization.

The land side 618 of the substrate 614 depicts a solder bump array that can also be referred to as a ball-grid array or the like. During processing, a dispenser (not pictured) is depositing a substantially continuous stream of a mass for a stress-relief layer 624, that has made contact with a solder first bump 616′ and a solder second bump 616″. The solder first bump 616′ and the solder second bump 616″ are analogous to a solder first bump 116′ and a solder second bump 116″ as seen in FIG. 1B, while the dispenser 120 is operated with the X-Y gantry 122 to deposit the substantially continuous stream of the SRL 124.

In an embodiment, flow of the substantially continuous stream of a mass for the stress-relief layer (SRL) 624 is carried out under conditions to cause the SRL 624 to at least partially flood around the solder first bump 616′ and the solder second bump 616″, such that the SRL 624 can substantially contact about half or more of the circumferences of the respective solder bumps.

FIG. 6B is a plan of the chip package 600 depicted in FIG. 6A during further processing according to an embodiment. After the dispenser (not pictured) has completed laying down a substantially continuous stream of the SRL 624, the SRL 624 includes an origin 623 where the dispenser began to eject the SRL 624 onto the substrate 614, and a terminus 625 where the dispenser stopped dispensing according to an embodiment. As depicted in FIG. 6B, a spiral pattern is laid down of the substantially continuous SRL 624. In an embodiment, processing includes a higher flow rate along the peripheral solder bumps 616 such that the SRL 624 can substantially surround at least about half the circumferences of the peripheral solder bumps 616. Thereafter, the flow rate is decreased for the interior solder bumps 616. In an embodiment, the X-Y gantry translational speed is modified where the dispenser changes directions to cause substantially the same amount of a mass of the SRL 624 to be metered while the X-Y gantry negotiates corners. In an embodiment, the X-Y gantry translational speed is not modified, but the flow rate of the dispenser is modified to be metered at different rates while the X-Y gantry negotiates corners. In any event, the amount of the SRL 624 that is metered to cover the solder first bumps 616 is an amount between about 5% and about 95% as set forth in this disclosure according to the various embodiments.

In an embodiment, other patterns can be achieved while forming the SRL 624. In an embodiment, a serpentine pattern can be dispensed where the solder bump count allows for a continuous stream of the SRL mass to be metered onto the land side 618 of the substrate 614.

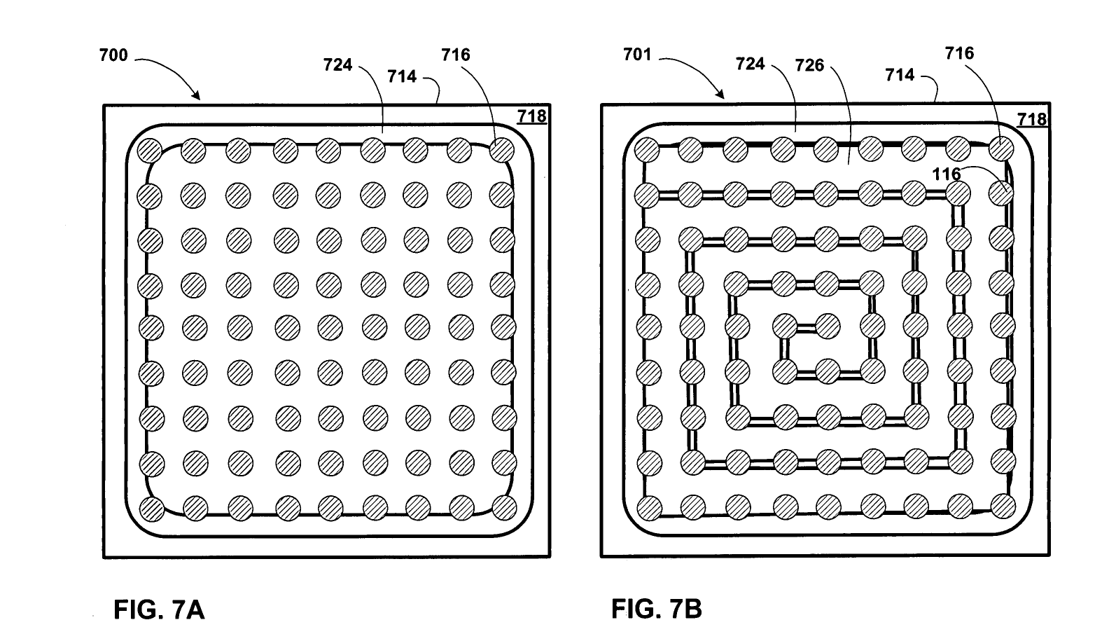

FIG. 7A is a plan of a chip package 700 during processing according to an embodiment. The chip package 700 includes a die (not pictured) that is coupled through a plurality of solder bumps on the land side thereof, one of which is designated with the reference numeral 716.

The land side 718 of the substrate 714 depicts a solder ball array. During processing a dispenser (not pictured) is depositing a substantially continuous stream of a stress-relief layer (SRL) 724 that forms a peripheral ring SRL 724 about the solder bumps 716.

FIG. 7B is a plan of the chip package 700 depicted in FIG. 7A during further processing according to an embodiment. In connection with flow of the peripheral ring SRL 724, a spiral, substantially continuous SRL 726 is formed to make contact with substantially all the solder bumps 716, including those contacted by the peripheral ring SRL 724.

In an embodiment, the peripheral ring SRL 724 and the substantially continuous SRL 726 are formed in a single, continuous dispensation of underfill material such that one pass of the X-Y gantry forms the peripheral ring SRL 724, whether it precedes, follows, or is formed simultaneously with the substantially continuous SRL 726. In any event, the amount of the underfill material is metered to cover the solder bumps 716 to an amount between about 5% and about 95% as set forth in this disclosure according to the various embodiments.

In an embodiment, other patterns can be achieved while forming the stress-relief layer 726. In an embodiment, a serpentine pattern can be dispensed where the solder bump count allows for a continuous stream of the stress-relief layer to be metered onto the land side 718 of the substrate 714.

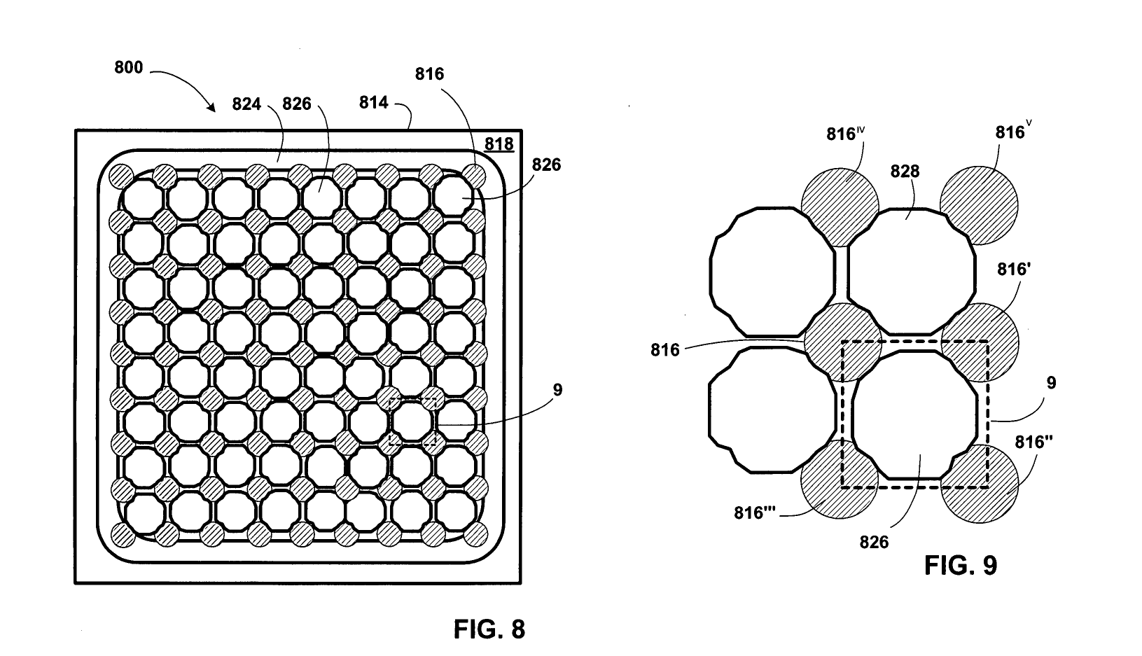

FIG. 8 is a plan of a chip package 800 during processing according to an embodiment. The chip package 800 includes a die (not pictured) that is coupled through a plurality of solder first bumps on the land side thereof, one of which is designated with the reference numeral 816.

The land side 818 of the substrate 814 depicts a solder bump array such as a ball-grid array or the like. In an embodiment, the peripheral solder bumps 816 are contacted with a peripheral ring stress-relief layer (SRL) 824.

The larger array of the solder bumps 816 is processed differently to achieve a stress-relief layer. During processing a dispenser (not pictured) ejects a discrete series of quanta of compositions upon the land side 818, which is analogous to a lower surface where the die (not pictured) is on top of a package such as the die 110 in FIG. 1C is disposed on top of the package 102. The discrete series of quanta of compositions is also referred to by the reference numeral 826 as an SRL polymer mass 826 in an embodiment. FIG. 8 depicts flow characteristics of the discrete series of quanta of compositions 824 as it encounters a solder first bump 816.

FIG. 9 is a detail of the chip package 800 depicted in FIG. 8. The chip package 800 details four solder bumps including a solder first bump 816, a solder second bump 816′ , a solder third bump 816″, and a solder fourth bump 816′″.

The respective solder first-through-fourth bumps 816, 816′, 816″, and 816′″ are arrayed around a stress-relief layer 824 that is referred to as an SRL polymer first mass 826, in a rectangular pattern 9 as also seen in FIG. 8. FIG. 9 depicts the SRL polymer first mass 824 to be contiguous with only the respective solder first-through-fourth bumps 816, 816′, 816″, and 816′″.

FIG. 9 also depicts a solder fifth bump 816^{IV} and a solder sixth bump 816^{V} that are contiguous to a portion of the stress-relief layer that is an SRL polymer second mass 826. The solder fifth bump 816^{IV} and solder sixth bump 816^{V} are in a rectangular pattern with the solder first bump 816 and the solder second bump 816′. Consequently, the SRL polymer second mass 826 is contiguous with only the solder first bump 816, the solder second bump 816′, the solder fifth bump 816^{IV} and the solder sixth bump 816^{V}.

For claiming purposes, an embodiment can refer to the solder fifth bump 816^{IV} as a solder third bump, and the solder sixth bump 816^{V} as a solder fourth bump. This relationship is in reference to the SRL polymer first mass 824 and the SRL polymer second mass 826.

Various embodiments are achievable by the permutation of the continuous deposition process and the discrete deposition process. For example, filled polymers are ejected to form an array of SRL polymer masses upon the land side 818 of the substrate 814. Further according to an embodiment, the height of the stress-relief layer is from about 5% of the solder bump exposed to about 95% thereof according to any of the embodiments set forth in this disclosure.

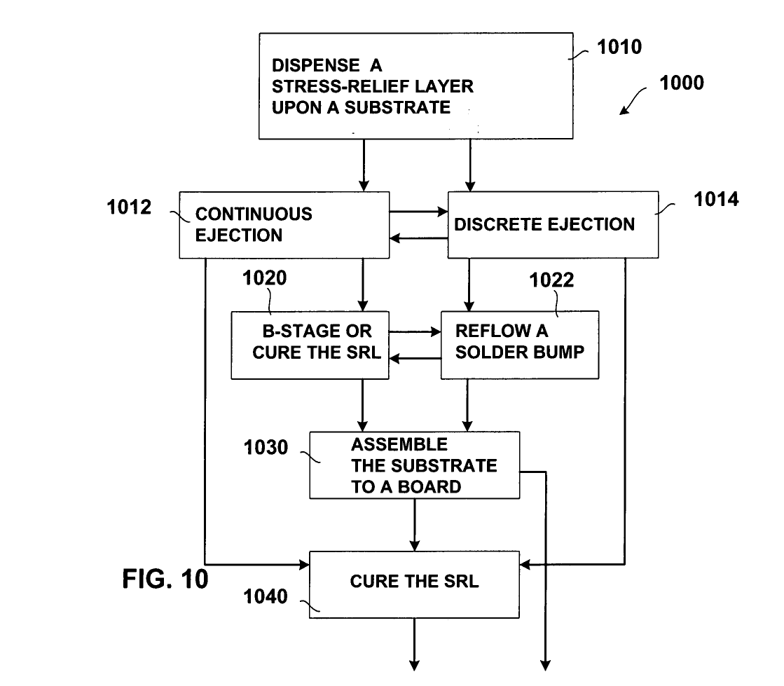

FIG. 10 is a process flow diagram 1000 according to an embodiment.

At 1010, the process includes dispensing a stress-relief layer (SRL) upon a substrate. In an embodiment, jet dispensing is carried out to form the stress-relief layer.

At 1012, the process includes ejecting a substantially continuous SRL mass upon the substrate. In an embodiment, the process includes a combination of ejecting a substantially continuous SRL mass and ejecting a discrete series (process 1014) of quanta of materials. In an embodiment the process terminates at 1012.

At 1014, the process includes ejecting a discrete series of quanta of an SRL mass to form the stress-relief layer upon the substrate. In an embodiment, the process includes a combination of ejecting a substantially continuous (process 1012) SRL mass and ejecting a discrete series of quanta of materials. In an embodiment the process terminates at 1014.

At 1020, the process includes curing the SRL. In an embodiment, the process includes a combination of curing the SRL and reflowing (process 1022) a first solder bump. In an embodiment, the process includes B-staging the SRL. B-staging includes increasing the viscosity of the polymer such that it can retain its shape until further processing. In an embodiment the process terminates at 1020.

At 1022, the process includes reflowing a first solder bump that abuts the SRL. In an embodiment, the process includes a combination of curing (process 1020) the SRL and reflowing a first solder bump. In an embodiment the process terminates at 1022.

In an embodiment, the process includes reflowing a first solder bump, followed in the same or a subsequent thermal process of curing the SRL.

At 1030, the process includes assembling the substrate to a board. In an example, the substrate is an interposer and the board is a motherboard. In an embodiment the process terminates at 1030.

At 1040, the process includes curing the SRL if the SRL has not yet been cured, or if the SRL has been B-stage cured, the curing is taken to completion. In an embodiment the process terminates at 1040.

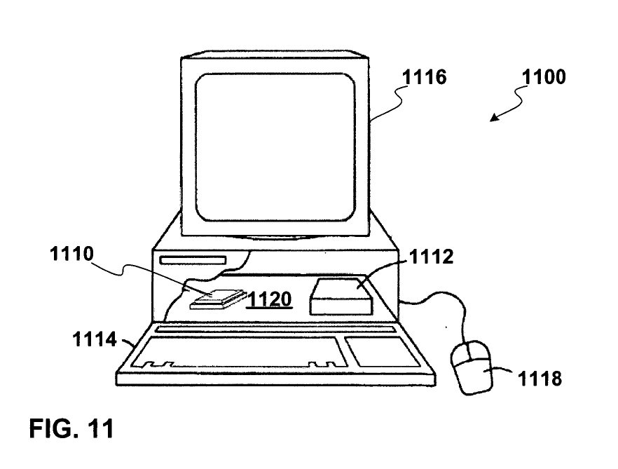

FIG. 11 is a depiction of a computing system according to an embodiment. The computing system 1100 includes a solder bump array with a stress-relief layer configuration according to an embodiment. One or more of the foregoing embodiments of the SRL configuration may be utilized in a computing system, such as a computing system 1100 of FIG. 11. The computing system 1100 includes at least one processor (not pictured), which is enclosed in a package 1110, a data storage system 1112, at least one input device such as keyboard 1114, and at least one output device such as monitor 1116, for example. The computing system 1100 includes a processor that processes data signals, and may include, for example, a microprocessor, available from Intel Corporation. In addition to the keyboard 1114, the computing system 1100 can include another user input device such as a mouse 1118, for example.

For purposes of this disclosure, a computing system 1 100 embodying components in accordance with the claimed subject matter may include any system that utilizes a microelectronic device system, which may include, for example, an SRL configuration that is coupled to data storage such as dynamic random access memory (DRAM), polymer memory, flash memory, and phase-change memory. In this embodiment, the SRL configuration is coupled to any combination of these functionalities by being coupled to a processor. In an embodiment, however, an SRL configuration set forth in this disclosure is coupled to any of these functionalities. For an example embodiment, data storage includes an embedded DRAM cache on a die. Additionally in an embodiment, the SRL configuration that is coupled to the processor (not pictured) is part of the system with an SRL configuration that is coupled to the data storage of the DRAM cache. Additionally in an embodiment, an SRL configuration is coupled to the data storage 1112.

In an embodiment, the computing system can also include a die that contains a digital signal processor (DSP), a micro controller, an application specific integrated circuit (ASIC), or a microprocessor. In this embodiment, the SRL configuration is coupled to any combination of these functionalities by being coupled to a processor. For an example embodiment, a DSP (not pictured) is part of a chipset that may include a stand-alone processor (in package 1 110) and the DSP as separate parts of the chipset. In this embodiment, an SRL configuration is coupled to the DSP, and a separate stress-relief layer configuration may be present that is coupled to the processor in package 1110. Additionally in an embodiment, an SRL configuration is coupled to a DSP that is mounted on the same board as the package 1110.

It can now be appreciated that embodiments set forth in this disclosure can be applied to devices and apparatuses other than a traditional computer. For example, a die can be packaged with an embodiment of the SRL configuration, and placed in a portable device such as a wireless communicator or a hand-held device such as a personal data assistant and the like. Another example is a die that can be packaged with an embodiment of the SRL configuration and placed in a vehicle such as an automobile, a locomotive, a watercraft, an aircraft, or a spacecraft.

The Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

1. A process comprising:
dispensing a polymer stress-relief layer upon a substrate lower surface under conditions to partially embed an electrical first bump disposed upon the lower surface; and
curing the stress-relief layer.

2. The process of claim 1, following curing the stress-relief layer, further including reflowing the electrical first bump.

3. The process of claim 1, wherein dispensing a polymer includes dispensing in a continuous action.

4. The process of claim 1, wherein dispensing the polymer stress-relief layer includes forming a substantially continuous stress-relief layer film between the electrical first bump and an electrical second bump that is spaced apart and adjacent to the electrical first bump.

5. The process of claim 1, wherein dispensing the polymer stress-relief layer includes forming a substantially continuous stress-relief layer film between the electrical first bump and a plurality of electrical subsequent bumps in excess of two, at least one of which is spaced apart and adjacent to the electrical first bump.

6. The process of claim 1, wherein dispensing the polymer stress-relief layer includes ejecting a substantially continuous polymer mass upon the lower surface that includes a ball grid array in excess of four electrical bumps including the electrical first bump.

7. The process of claim 1, wherein dispensing the polymer stress-relief layer includes ejecting a discrete series of quanta of polymer masses upon the lower surface that includes a ball grid array in excess of four electrical bumps including the electrical first bump.

8. The process of claim 1, wherein dispensing the polymer stress-relief layer includes ejecting a polymer first mass and a polymer second mass upon the lower surface that includes a ball grid array of at least six electrical bumps:
wherein the electrical first bump is in a rectangular pattern with an electrical second bump, an electrical third bump, and an electrical fourth bump, wherein the polymer first mass is ejected contiguous with only the electrical first bump, the electrical second bump, the electrical third bump, and the electrical fourth bump; and
wherein the electrical first bump and the electrical second bump are in a rectangular pattern with an electrical fifth bump and an electrical sixth bump, wherein the polymer second mass is ejected contiguous with only the electrical first bump, the electrical second bump, the electrical fifth bump, and the electrical sixth bump.

9. The process of claim 1, wherein the electrical first bump includes a first height, and wherein dispensing the polymer stress-relief layer includes dispensing in a depth range against the electrical first bump in a range from about 5 percent the first height to about 95 percent the first height.

10. An article comprising:
a mounting substrate including a lower and an upper surface;
an electrical first bump disposed on the lower surface;
a stress-relief layer disposed on the lower surface, wherein the electrical first bump is at least partially embedded in the stress-relief layer, and wherein at least a portion of the electrical first bump is exposed below the stress-relief layer; and
a die disposed upon the upper surface that is coupled to the electrical first bump.

11. The article of claim 10, wherein the stress-relief layer includes an organic material.

12. The article of claim 10, wherein the stress-relief layer includes an organic material, and wherein the organic material includes a filler particulate.

13. The article of claim 10, wherein the stress-relief layer includes a first stress-relief layer, wherein the first stress-relief layer is disposed between the electrical first bump, an electrical second bump that is spaced apart and adjacent to the electrical first bump, an electrical third bump that is spaced apart and adjacent to the electrical first bump, and an electrical fourth bump that is spaced apart and adjacent to the electrical first bump, the stress-relief layer further including:
a second stress-relief layer disposed between the electrical first bump and an electrical fifth bump that is spaced apart and adjacent to the electrical first bump.

14. The article of claim 10, wherein the electrical first bump is in a rectangular pattern with an electrical second bump, an electrical third bump, and an electrical fourth bump, and wherein the stress-relief layer is disposed in about the geometric center of the rectangular pattern.

15. The article of claim 10, wherein the electrical first bump is in a rectangular pattern with an electrical second bump, an electrical third bump, and an electrical fourth bump, and wherein the stress-relief layer is disposed contiguous with only the electrical first bump, the electrical second bump, the electrical third bump, and the electrical fourth bump.

16. The article of claim 10, wherein the polymer stress-relief layer includes a polymer first mass and a polymer second mass disposed upon the lower surface that includes a ball grid array of at least six electrical bumps:
wherein the electrical first bump is in a rectangular pattern with an electrical second bump, an electrical third bump, and an electrical fourth bump, wherein the polymer first mass is contiguous with only the electrical first bump, the electrical second bump, the electrical third bump, and the electrical fourth bump; and
wherein the electrical first bump and the electrical second bump are in a rectangular pattern with an electrical fifth bump and an electrical sixth bump, wherein the polymer second mass is contiguous with only the electrical first bump, the electrical second bump, the electrical fifth bump, and the electrical sixth bump.

17. The article of claim 10, wherein the electrical first bump includes a first height, and wherein the polymer stress-relief layer includes a depth range against the electrical first bump in a range from about 5 percent the first height to about 95 percent the first height.

18. A package comprising:
a board including a bottom and a land side;
a substrate including a lower surface and an upper surface, wherein the board is disposed on the substrate land side;
a solder first bump disposed on the lower surface;
a stress-relief layer disposed on the lower surface, wherein the solder first bump is at least partially embedded in the stress-relief layer, and wherein at least a portion of the solder first bump is exposed above the stress-relief layer; and
a die dispose upon the upper surface.

19. The package of claim 18, wherein the stress-relief layer is a first stress-relief layer, wherein the first stress-relief layer is disposed between the solder first bump and a solder second bump that is spaced apart and adjacent to the solder first bump, the package further including:
a second stress-relief layer disposed between the solder first bump and a solder third bump that is spaced apart and adjacent to the solder first bump.

20. The package of claim 18, wherein the solder first bump is in a rectangular pattern with a solder second bump, a solder third bump, and a solder fourth bump, and wherein the stress-relief layer is disposed in about the geometric center of the rectangular pattern.

21. The package of claim 18, wherein the solder first bump is in a rectangular pattern with a solder second bump, a solder third bump, and a solder fourth bump, and wherein the stress-relief layer is disposed contiguous with only the solder first bump, the solder second bump, the solder third bump, and the solder fourth bump.

22. The package of claim 18, wherein the polymer stress-relief layer includes a polymer first mass and a polymer second mass disposed upon the lower surface that includes a ball grid array of at least six solder bumps:
wherein the solder first bump is in a rectangular pattern with a solder second bump, a solder third bump, and a solder fourth bump, wherein the polymer first mass is contiguous with only the solder first bump, the solder second bump, the solder third bump, and the solder fourth bump; and
wherein the solder first bump and the solder second bump are in a rectangular pattern with a solder fifth bump and a solder sixth bump, wherein the polymer second mass is contiguous with only the solder first bump, the solder second bump, the solder fifth bump, and the solder sixth bump.

23. The package of claim 18, wherein the solder first bump includes a first height, and wherein the polymer stress-relief layer includes a depth range against the solder first bump in a range from about 5 percent the first height to about 95 percent the first height.

24. A computing system comprising:
a microelectronic die;
a mounting substrate including a lower and an upper surface;
a solder first bump disposed on the lower surface;
a stress-relief layer disposed on the lower surface, wherein the solder first bump is at least partially embedded in the stress-relief layer, and wherein at least a portion of the solder first bump is exposed above the stress-relief layer;
a die disposed upon the upper surface and coupled to the solder first bump; and
at least one of an input device and an output device coupled to the solder first bump.

25. The computing system of claim 24, wherein the computing system is disposed in one of a computer, a wireless communicator, a hand-held device, an automobile, a locomotive, an aircraft, a watercraft, and a spacecraft.

26. The computing system of claim 24, wherein the die is selected from a data storage device, a digital signal processor, a micro controller, an application specific integrated circuit, and a microprocessor.
